(19) United States
(12) Patent Application Publication
(10) Pub. No.: US 2025/0386720 A1
(43) Pub. Date: Dec. 18, 2025

(54) PHOTORESIST PASSIVATION OF DEFECTS IN PEROVSKITE LAYERS

(71) Applicant: Alliance for Sustainable Energy, LLC, Golden, CO (US)

(72) Inventors: Ross Allen KERNER, Wheat Ridge, CO (US); Axel Finn PALMSTROM, Golden, CO (US); Kelly Robert SCHUTT, Wheat Ridge, CO (US); Kylie THOMPSON, Golden, CO (US)

(21) Appl. No.: 19/242,729

(22) Filed: Jun. 18, 2025

Related U.S. Application Data
(60) Provisional application No. 63/661,177, filed on Jun. 18, 2024.

(51) Int. Cl. H10K 71/20; H10K 30/40

(52) U.S. Cl. CPC H10K 71/231; H10K 30/40

(57) ABSTRACT

The present disclosure relates to a method that includes, in order, applying a liquid to a first surface of a perovskite layer, the perovskite layer having an average thickness defined by a distance between the first surface and a second surface and irradiating the second surface with a light, where the perovskite layer includes a void that penetrates into the first surface and at least a portion of the thickness, the applying results in at least a portion of the liquid at least partially filling the void, and the irradiating results in the liquid in the void reacting to form a solid.

### CROSS-REFERENCE TO RELATED APPLICATIONS

This application claims priority from U.S. Provisional Patent Application No. 63/661,177 filed on Jun. 18, 2024 and its associated appendix, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### BACKGROUND

The properties of halide perovskite absorber layers permit very thin layers (0.3-1.0 microns) of this material to be provided in solar cell/module applications, resulting in power conversion efficiencies rivaling silicon photovoltaics. However, as-deposited and subsequently processed thin layers of all kinds, particularly at large scale, contain numerous physical defects. Specifically, pinholes—gaps in the layer due to coating imperfections that can range in size from 1 nm to many microns in scale—as well as other handling-related scratches or punctures through the layer can result in the creation of electronic shunts in the completed device that decrease efficiency and stability. Furthermore, monolithic perovskite modules include a set of “P1”, “P2”, “P3”, and “P4” scribes to enable series interconnection where the “P2” scribe is essentially an intentional scratch or ablation through the perovskite layer. Scribing results in surface (material) defects and device layer stack sequences that are undesirable (e.g. direct metal/perovskite contact when buffer layer(s) typically separate them). Perovskite solar cell research and development, often limited to small, laboratory-scale synthesis methods and devices, often strive to make unrealistically perfect, defect-free perovskite thin layers, which still frequently suffer from the formation of defects in the perovskite layers, have limited applicability to commercially scaled processes. Thus, there is a need for improved methods for making photovoltaic modules, at full manufacturing-scale, where the effects of defects present in the perovskite layer have been minimized and/or eliminated.

### SUMMARY

An aspect of the present disclosure is a method that includes, in order, applying a liquid to a first surface of a perovskite layer, the perovskite layer having an average thickness defined by a distance between the first surface and a second surface and irradiating the second surface with a light, where the perovskite layer includes a void that penetrates into the first surface and at least a portion of the thickness, the applying results in at least a portion of the liquid at least partially filling the void, and the irradiating results in the liquid in the void reacting to form a solid. In some embodiments of the present disclosure, the void may be completely filled by the solid.

In some embodiments of the present disclosure, the average thickness of the perovskite layer, without voids, may result in essentially zero transmission of the light between the wavelengths of 200 nm and 400 nm from the second surface to the first surface. In some embodiments of the present disclosure, the light may include a wavelength of less than or equal to 500 nm. In some embodiments of the present disclosure, the average thickness may be between 400 nm and 1000 nm.

In some embodiments of the present disclosure, the method may further include, before the applying, depositing an intervening layer onto the first surface of the perovskite layer. In some embodiments of the present disclosure, the intervening layer may include at least one of an organic, an oxide, a carbonaceous material, or a combination thereof.

In some embodiments of the present disclosure, the method may further include, after the irradiating, removing unreacted liquid remaining on at least one of the first surface of the perovskite layer or on the intervening layer. In some embodiments of the present disclosure, the removing may be performed physically, by gravity, by use of a removal liquid, or a combination thereof. In some embodiments of the present disclosure, at least one of the applying, irradiating, or removing is performed at a temperature between 10° C. and 100° C. In some embodiments of the present disclosure, the void may include at least one of a hole, a pin-hole, a crack, a thinner portion of the perovskite layer, a scribe, a grain boundary, or a combination thereof.

In some embodiments of the present disclosure, the liquid includes a monomer. In some embodiments of the present disclosure, the monomer may include at least one of an alkene, an epoxide, an ester, an acrylate, phenol, a phenoloic, azides, an isoprene, an oxetane, a coumarin, an anthracene, a maleimide, a furan, styrene, or a combination thereof. In some embodiments of the present disclosure, the liquid may further include a polymerizing agent. In some embodiments of the present disclosure, the polymerizing agent may include a radical initiator. In some embodiments of the present disclosure, the solid includes a cured form of the monomer. In some embodiments of the present disclosure, the cured form of the monomer may include at least one of a polyether, a polyacrylate, a polyalkene, a phenolic resin, a polyester, polystyrene, or a combination thereof.

In some embodiments of the present disclosure, during the applying, the liquid may have a viscosity between 1 cSt and 10,000 cSt or between 1,000 cSt and 5,000 cSt.

An aspect of the present disclosure is a device that includes a perovskite layer having a void, where the void is at least partially filled with at least one of a polymer, a resin, or a combination thereof.

### BRIEF DESCRIPTION OF DRAWINGS

Some embodiments are illustrated in referenced figures of the drawings. It is intended that the embodiments and figures disclosed herein are to be considered illustrative rather than limiting.

FIGS. 1, 2, and 3A illustrate methods for treating devices having perovskite layers containing defects, according to some embodiments of the present disclosure.

FIG. 3B illustrates a perovskite layer positioned on a substrate with voids having a different aspect ratio compared to those illustrated in FIGS. 2 and 3A, according to some embodiments of the present disclosure.

FIG. 4 illustrates a relationship between the thickness of a perovskite layer, percentage of light transmittance, and photoresist curing, according to some embodiments of the present disclosure.

FIG. 5 illustrates an exemplary method for treating a device having a perovskite layer with various defects, according to some embodiments of the present disclosure.

FIG. 6 illustrates an optical micrograph of a halide perovskite film that was treated using methods described herein, according to some embodiments of the present disclosure.

FIG. 7 illustrates how the methods described herein may be used multiple times during the fabrication of a device, according to some embodiments of the present disclosure.

FIG. 8 illustrates (Panel A) a photograph of a device where the left side was treated using the methods described herein and the right side was untreated and (Panel B) a comparison of current-voltage curves obtained for both devices treated using the methods described herein versus untreated, according to some embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### REFERENCE NUMERALS

100 . . . method
105 . . . substrate
110 . . . depositing (perovskite layer)
112 . . . perovskite precursors
115 . . . intermediate device (with voids)
120 . . . applying (of liquid photoresist)
122 . . . liquid (i.e., photoresist)
130 . . . irradiating (underside of device stack to cure photoresist)
132 . . . light
140 . . . removing (to remove uncured photoresist)
142 . . . clean removal liquid
146 . . . used removal liquid
150 . . . depositing (of subsequent layers, e.g., electrode)
155 . . . improved device
210 . . . perovskite layer
215 . . . void (i.e., defect)
220 . . . liquid layer (of photoresist)
232 . . . light source
234 . . . light
240 . . . solid
300 . . . depositing (of intervening layer)
310 . . . intervening layer

### DETAILED DESCRIPTION

The present disclosure relates to the use of a negative photoresist and/or developers compatible with perovskite materials to passivate physical defects in perovskite layers that would, when left untreated, lead to shunts in the photovoltaic devices using the defective perovskite layers. As described herein, according to some embodiments of the present disclosure, after a perovskite layer is deposited onto the top layer of a stack (including, for example, at least one of a substrate layer, an electrode, transparent conductors, a charge transport layer, and/or a buffer layer), a negative photoresist may be deposited onto the top surface of the perovskite layer. As shown herein, a negative photoresist crosslinks under UV, so regions exposed to UV will cure and remain on the device stack as a solid after unexposed liquid, uncured photoresist remaining on unexposed regions is removed. A positive photoresist works in the opposite way: photoresist positioned on UV exposed regions remain liquid and are subsequently removed and unexposed regions cure/solidify and remain in/on the device. As described herein, portions of a perovskite layer that are essentially defect-free can act as a photomask. Therefore, a negative photoresist is utilized so that only scribes, pinholes, and/or other defects (i.e., voids) are selectively filled by liquid photoresist, exposed to UV, and subsequently cured. As a result, the scribes, pinholes, and/or other defects are effectively filled with cured photoresist, thereby eliminating or minimizing the possibility of shunts forming in the final perovskite-containing device.

In some embodiments of the present disclosure, a liquid photoresist may be applied to the surface of a perovskite layer via solution processing using a solvent compatible with the perovskite material. Voids present in the perovskite layer, e.g., holes, triple grain boundaries (a region where three grain boundaries merge), and even very thin regions (e.g., less than about 200 nm or less than about 100 nm) may be filled and/or covered with the liquid photoresist. The subsequent application of light (e.g., ultraviolet light) through the underlying layers of the device stack and into the overlaying perovskite layer results in the curing of the liquid photoresist into a solid in only those areas where the light impinges upon and/or passes through perovskite layer voids, resulting in the irradiation of the liquid photoresist. As a result, these specific areas, the voids present in the perovskite layer, holes, scribe lines etc., are selectively filled with the cured/solidified photoresist. Next, a solvent compatible with the perovskite is used to wash away any remaining uncured photoresist present on the perovskite layer, leaving the perovskite unharmed (and possibly enhanced, e.g., solvent treating of a perovskite surface can result in beneficial consequences) and the holes filled with solid. As the light, e.g., UV light, initiates the curing of the liquid photoresist, any device layers between the light source and the liquid photoresist filling the physical defects in a perovskite layer must be at least partially transparent to the light used to initiate the curing of the liquid photoresist.

A situation where the methods described herein may be used in the manufacture of perovskite modules, is after the metallization step of the entire surface area of the modules. In this example, cured photoresist remaining in the voids prevents or minimizes shunts from forming at defect points under forward and/or reverse bias and eliminates other problems that would otherwise occur if the voids were left untreated during subsequent processing steps (e.g., deposition of a charge transport layer and/or a conducting electrode). The cured photoresist remains incorporated in the perovskite layer and in the improved device, e.g., solar cell and/or solar module, and physically “plugs” the voids, providing a physical barrier that prevents the infiltration of materials used to manufacture the device layers subsequently deposited onto the perovskite layer.

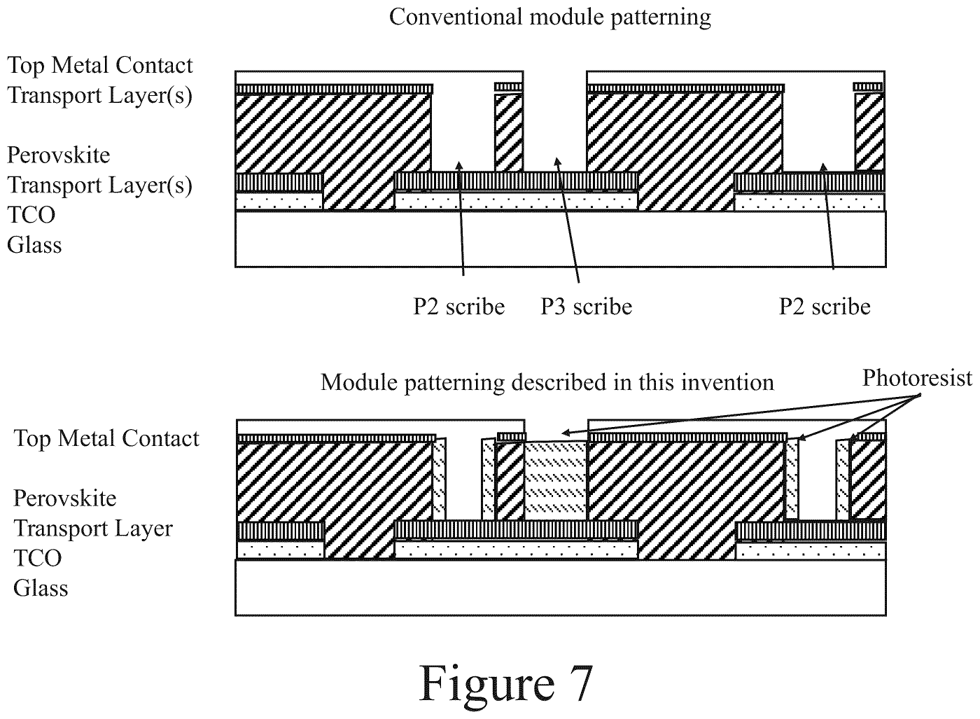

Further, in some embodiments of the present disclosure, methods described herein may be applied to P1, P2, P3, and/or P4 scribes in the perovskite layers of photovoltaic modules using external (conventional photolithography) or internal photomasks: e.g., a metal strip deposited in the center but not the edges of a P2 scribe and/or local deposition techniques like spray coating (using a narrow stream) and/or ink jet printing. This concept is illustrated in FIG. 7.

Thus, the present disclosure relates to methods that can minimize and/or eliminate physical defects and/or electrical defects present in perovskite layers resulting from the manufacturing processes used to synthesize perovskite layers and/or downstream processing steps, post perovskite deposition where said defects can result in electronic defects (shunts) in finished solar cells and/or modules. As with all technologies, defects are manageable but unavoidable and their likelihood in thin layers scales proportionally with increases in the surface area of the devices (e.g., cells and modules). Full-scale modules have surface areas typically between 0.5 m² and 2 m². Further, industrial manufacturing of perovskite layers having surface areas in that range are expected to result in larger variations in product quality than what has been demonstrated to date in laboratory-scale manufacturing methods, which will result in reduced device performance. Techniques like blade coating, slot die-coating, and/or curtain-coating for depositing perovskite layers may result in greater variation in the physical characteristics of the resulting layers, compared to laboratory-scale liquid deposition methods like spin-coating. For example, full-scale manufacturing methods may result in greater variation in metrics such as average perovskite layer thicknesses and the number of defects per unit area, e.g., pin-holes, voids, etc. Such physical defects may subsequently result in shunts in the final solar cells/modules and, consequently, reduced performance metrics (e.g., photoconversion efficiencies, fill factors, etc.). The methods described herein provide scalable processes for substrate architectures that can minimize and/or eliminate such negative consequences resulting from perovskite layers having such physical and/or electrical defects.

In some embodiments of the present disclosure, after a perovskite layer is deposited onto a substrate of glass and/or transparent conducting oxide, a liquid layer of a photoresist may be applied to the outer surface of the perovskite layer and/or the outer layer of an intervening layer deposited on the perovskite layer (e.g., a thin organic or oxide layer, such as a fullerene or naphthalene diimide, or tin oxide). As shown herein, in some embodiments of the present disclosure, an intervening layer may act as a protective layer that prevents a liquid photoresist from degrading an underlying perovskite layer, either due to solubility and/or reactivity. As used herein, a “substrate” refers to one or more layers arranged in a stack. So, a substrate may be a single layer, e.g., a glass layer, or a substrate may be one or more layers of different materials, each having a specific defined purpose, e.g., a conducting layer, a transparent conducting layer, a charge transport layer, a buffer layer, etc.

The applying of a liquid layer of a photoresist may be achieved via a solution processing method using a liquid that is preferably compatible with the perovskite material and/or the intervening layer; e.g., a liquid with a negligible solubility for the perovskite material and/or intervening layer and minimum reactivity with the perovskite material and/or intervening layer. After a liquid layer of photoresist has been applied to a perovskite layer and/or intervening layer, a light source may be positioned on the “front side” of the substrate, such that the light generated by the light source is transmitted through the substrate and into at least a portion of the perovskite layer. Portions of a perovskite layer having a minimum thickness will absorb all of, or most of the light, preventing light from being transmitted to the overlying liquid layer of photoresist, thereby preventing the photoresist positioned over these areas from solidifying (i.e., polymerizing and/or curing). However, areas having imperfections such as voids, pin-holes, cracks, and/or significantly less than the minimum perovskite layer thicknesses, will transmit light through the perovskite layer and/or into at least a portion of the perovskite layer's thickness, resulting in the irradiating of the liquid photoresist positioned in these portions of the device and the subsequent solidification of the photoresist in those specific areas. Once the areas having imperfections have been filled with solidified photoresist, a solvent, preferably compatible with the perovskite material, may be used to remove any remaining liquid, leaving an improved, passivated, and/or void-free perovskite layer behind. Among other things, the solid-filled imperfections may prevent the formation of shunts in subsequent fabrication steps (e.g., the depositing of a top electrode), resulting in an improved device having superior physical properties and performance metrics when compared to an identical device stack that was not processed/manufactured using a photoresist.

Further, in some embodiments of the present disclosure, the methods describe herein may be applied to scribes (e.g., P1, P2, P3, and/or P4 scribes) in a perovskite photovoltaic module, using for example slot-die coating, blade-coating, gravure coating, or localized deposition techniques such as spray coating and/or ink jet printing, in narrow liquid streams targeting just the scribes.

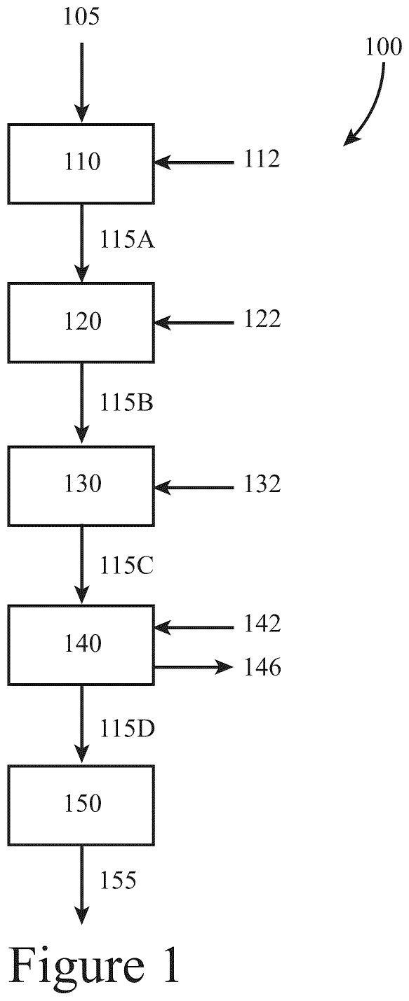

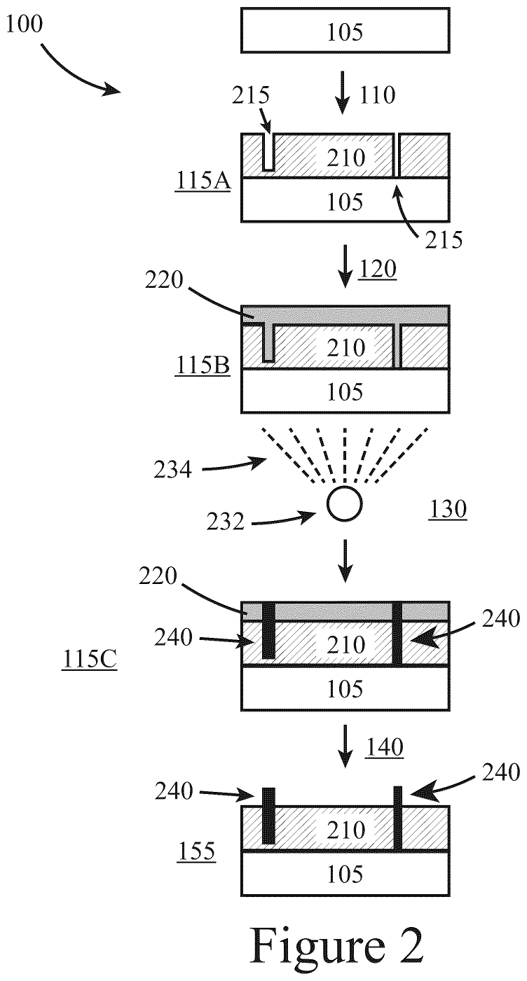

FIGS. 1 and 2 illustrate a method 100 for treating an intermediate device 115A that includes a substrate 105 and a perovskite layer 210 having several defects, i.e., voids 215, according to some embodiments of the present. FIG. 1 illustrates the steps of the method 100,, whereas FIG. 2 illustrates the resultant intermediate devices resulting from the method steps of FIG. 1. Referring to FIGS. 1 and 2, a method 100 may begin with the depositing 110 of a perovskite layer 210 onto a substrate 105. As defined herein, a substrate 105 may be any layer or combination of layers onto which a perovskite layer 210 may be deposited. Thus, a substrate 105 may include at least one of a glass layer, a polymer layer (e.g., polyethylene naphthalate, polyethylene terephthalate, poly(vinyl chloride), and/or polyvinylpyrrolidone), a conducting layer (e.g., a conducting oxide), and/or a charge transport layer (CTL) (e.g., a hole transport layer (HTL) and/or an electron transport layer (ETL)). Importantly, a substrate 105 should be at least partially transparent to the light used to enable the subsequent solidification of the later-applied liquid photoresist. Therefore, in some embodiments of the present disclosure, a substrate 105 may include a glass layer and/or a layer of a transparent conducting oxide, e.g., at least one of doped indium oxide (In₂O₃:Sn, In₂O₃:Mo, In₂O₃:Ti, and/or In₂O₃:H), a doped zinc oxide (ZnO:Al, ZnO:Ga, and/or ZnO:Ti), a doped tin oxide (SnO₂:F, SnO₂:Sb, SnO₂:Ta, and/or SnO₂:Nb), and/or a doped titanium oxide (TiO₂:Nb).

In some embodiments of the present disclosure, a substrate 105 may include a transparent metal oxide layer that has been treated with a self-assembled molecule to form a self-assembled monolayer (SAM) on the surface of the transparent metal oxide layer, such that the combination of the SAM with the transparent metal oxide layer results in a composite structure having hole transport characteristics. Examples of self-assembled molecules for forming SAMs, include molecules having anchoring groups that include at least one of a phosphonic acid group (e.g. [2-(9H-Carbazol-9-yl)ethyl]phosphonic acid, (2-(3,6-dimethoxy-9H-carbazol-9-yl)ethyl)phosphonic acid), a carboxylic acid group (e.g. benzoic acid), a sulfonic acid group, a trimethoxysilane group (e.g. aminopropyltrimethoxysilen), a cyanoacetic acid group, and/or another acid group.

In some embodiments of the present disclosure, a device stack that includes a perovskite layer that has been treated using the methods described herein, e.g., the use of a negative photoresist to minimize and/or eliminate the negative affects cause by physical defects initially present in the perovskite layer, may be either an n-i-p device or a p-i-n device. For example, a p-i-n device may have a general device architecture as follows:
substrate/first electrode (transparent)/HTL/perovskite layer/ETL/second electrode
   A specific example of a p-i-n device stack is as follows:
Glass/TCO/NiOx/SAM/perovskite/C60/ALD SnOx/Metal (Ag, Au).
   An n-i-p device may have a general device architecture as follows:
substrate/first electrode (transparent)/ETL/perovskite layer/HTL/second electrode
   A specific example of a n-i-p device stack is as follows:
Glass/TCO/SnOx/perovskite/Spiro-OMeTAD/Metal

Referring again to FIGS. 1 and 2, the depositing 110 of a perovskite layer 210 onto a substrate 105 may be achieved using a variety of deposition methods known in the art, for example, solution deposition methods and/or vapor-phase deposition methods. Solution processing methods may include at least one of spin-coating, curtain-coating, blade-coating, dip-coating, slot-die coating, gravure coating, bar coating, and/or spray coating of a perovskite precursor 112 solution onto a substrate 105, forming a liquid layer of the perovskite precursor solution (not shown) on the substrate 105, followed by a crystallizing step achieved by at least one of annealing (i.e., thermally treating) the liquid perovskite precursor layer, solvent-exchange, and/or contacting the liquid perovskite precursor layer with a gas stream, resulting in the transformation of the liquid perovskite precursor layer into a solid perovskite layer 210. Vapor phase deposition methods for forming perovskite layer 210 include evaporation, flash evaporation, close-space sublimation, pulsed laser deposition, chemical vapor deposition, and/or vapor transport deposition.

In general, the term “perovskite” refers to compositions having a network of corner-sharing BX₆ octahedra resulting in the general stoichiometry of ABX₃. For example, metal halide perovskites, may organize into three-dimensional (3D) cubic or near-cubic symmetry crystalline structures constructed of a plurality of corner-sharing BX₆ octahedra. In the general stoichiometry for a perovskite, ABX₃, X is an anion and A and B are cations, typically of different sizes. A perovskite 100 may have an α-phase structure characterized by eight BX₆ octahedra surrounding a central A-cation, where each octahedra is formed by six X-anions surrounding a central B-cation, where each of the octahedra are linked together by “corner-sharing” of anions, X.

However, a perovskite can assume other crystal systems while still maintaining the criteria of an ABX₃ stoichiometry with neighboring BX₆ octahedra connected by X anion corner-sharing. Thus, in addition to perovskites in the cubic phase having a tilt angle of 180 degrees, a perovskite may also assume and interconvert between a tetragonal crystalline phase and/or an orthorhombic crystalline phase, where the adjacent octahedra are tilted relative to the 180 degrees (e.g. reversible phase changes in response to temperature). Further, the elements used to construct a perovskite, A-cations, B-cations, and X-anions, may result in 3D non-perovskite structures; i.e., structures where neighboring BX₆ octahedra are not X-anion corner-sharing and/or do not have a unit structure that simplifies to the ABX₃ stoichiometry. Examples include a non-perovskite structure constructed of face-sharing BX₆ octahedra resulting in a hexagonal crystalline structure and a non-perovskite structure constructed of edge-sharing BX₆ octahedra resulting in a variety of lower symmetry hexagonal, trigonal, monoclinic, or triclinic crystalline structures. A plethora of materials related to the perovskite material family may also include mixed BX₆ linkages within the same crystal structure, including face-, edge-, and corner-sharing, whether intentionally targeted structures or as a result of high defect density (e.g. twin boundaries) within a predominantly cubic perovskite material.

In addition, the elements used to construct a perovskite, as described above, A-cations, B-cations, and X-anions, may result in non-3D (i.e., lower dimensional structures) perovskite-like structures such as two-dimensional (2D) structures, one-dimensional (1D) structures, and/or zero-dimensional (0D) structures. Such lower dimensional, perovskite-like structures still include the BX₆ octahedra, and depending on the dimensionality, e.g., 2D or 1D, may still maintain a degree of X-anion corner-sharing. However, the X-anion corner-sharing connectivity of neighboring octahedra of such lower dimensional structures, i.e., 2D, 1D, and 0D, is disrupted by intervening A-cations. Such a disruption of the neighboring octahedra, can be achieved by, among other things, varying the size of the intervening A-cations. For simplification, the term “perovskite” is used herein to include corner-sharing crystal structures, and non-corner-sharing crystal structures, as well as each of 3D, 2D, 1D, and 0D crystal structures.

In some embodiments of the present disclosure, a perovskite layer may include at least one A-cation of MA, FA, Cs, guanidinium, and/or phenethylammonium, at least one B-cation of tin and/or lead, and at least one X-anion of a halogen and/or a pseudo-halogen (e.g., thiocyanate (SCN⁻), formate (HCOO⁻), acetate, tetrafluoroborate (BF4⁻)).

Referring again to FIGS. 1 and 2, depositing 110 a perovskite layer 210 onto a substrate 105 may result in an intermediate device 115A characterized by defects present in the perovskite layer 210. Among other things, such defects may include one or more voids 215 present in the perovskite layer 210. Among other things, a void 215 may include one or more holes, pin-holes, and/or cracks. In some embodiments of the present disclosure, a void 215 may pass completely through the thickness of a perovskite layer 210, or a void 215 may only penetrate partially into the thickness of a perovskite layer 210. In some embodiments of the present disclosure, a void 215 may simply be a portion of the perovskite layer 210 having less than an optimum, targeted thickness, resulting, for example, from processing errors during blade-coating of perovskite precursors 112 onto a substrate 105. In some embodiments of the present disclosure, a void 215 may have an average diameter in the plane of the perovskite layer 210 of less than or equal to one centimeter or an average diameter between 1 nm and 10 mm. Referring again to FIG. 2, voids 215 are illustrated as penetrating from the top surface of the perovskite layer 215 and extending vertically downwards towards the underlying substrate 105. This is shown for exemplary purposes. In some embodiments of the present disclosure, a void 215 may start at the interface created by the deposition of the perovskite layer 210 onto the substrate 210 and extend into at least a portion of the perovskite layer 210 in the direction of the top facing surface of the perovskite layer. Further, a void 215 may be irregular in shape and traverse portions of the perovskite layer 210 at any angle between vertical and horizontal to the thickness direction of the perovskite layer 210.

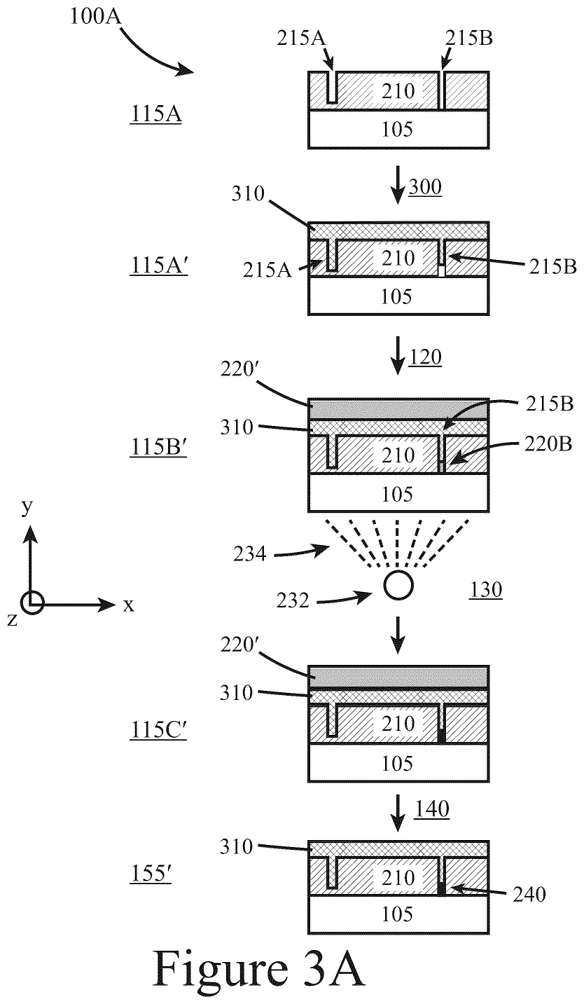

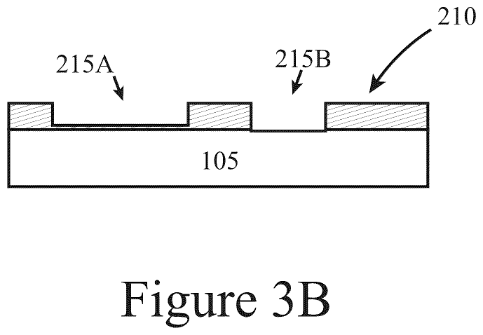

Referring again to FIGS. 1 and 2, in some embodiments of the present disclosure, after the depositing of a perovskite layer 210, a method 100 may proceed with the applying 120 of a liquid 122 photoresist directly onto a perovskite layer 210, resulting in a liquid layer 220 of photoresist positioned on the perovskite layer 210. However, in some embodiments of the present disclosure, as illustrated in FIG. 3A, a method 100A may include a depositing 300 of an intervening layer 310 onto a perovskite layer 210 before applying 120 a liquid 122 photoresist onto the intermediate device 115A. In some instances, e.g., when a particular perovskite and/or photoresist composition may react and/or the perovskite could be solubilized by the liquid photoresist, an intervening layer 310 may be utilized as a protective barrier to prevent or minimize degradation of the perovskite by interactions with the liquid photoresist. In some embodiments of the present disclosure, an intervening layer 310 may be constructed of a carbonaceous material such as a fullerene, graphene, and/or a carbon nanotube (e.g., single-walled carbon nanotubes, double-walled carbon nanotubes, and/or multi-walled carbon nanotubes). In some embodiments of the present disclosure, an intervening layer 310 may be constructed of a metal oxide, for example, tin oxide, nickel oxide, titanium oxide, zinc oxide, aluminum-doped zinc oxide, molybdenum oxide, vanadium oxide, indium tin oxide, and/or zinc tin oxide. In some embodiments of the present disclosure, an intervening layer 310 may include two or more layers, e.g., a first layer constructed using at least one of a carbonaceous material and/or organic material, and a second layer constructed using a metal oxide. An intervening layer 310 may be applied by a variety of methods known in the art. For example, fullerenes may be deposited by solution processed PCBM or thermally evaporated C60. Metal oxides may be deposited via solution processed nanoparticles in an “orthogonal” solvent (orthogonal meaning it doesn't dissolve the perovskite, so non-polar such as IPA, chlorobenzene, toluene, anisole, etc.). Further, metal oxides may be sputtered and/or deposited via ALD, but with an interlayer first to avoid damaging the perovskite.

Referring again to FIG. 3A, in some embodiments of the present disclosure, the material used to construct an intervening layer 310 may penetrate into at least some of the voids 215 present in the underlying perovskite layer 210. In some embodiments of the present disclosure, the material used to construct an intervening layer 310 may completely fill a void 215A and/or only partially fill a void 215B. Whether or not a void 215 is partially filled, completely filled, or remains completely unfilled by the material used to construct an intervening layer 310, may depend on, among other things, the dimensions of the void 215, the material used to make the intervening layer 310, the physical properties of the perovskite composition and/or the intervening layer's composition, and/or the method used for depositing 300 the intervening layer 310.

Referring again to FIGS. 2 and 3, in either case, with an intervening layer 310 (e.g., method 100A of FIG. 3A) or without an intervening layer 310 (e.g., method 100 of FIG. 2), a method may proceed with the applying of a liquid 122 photoresist to an intermediate device (115A in FIG. 2 or 115A′ in FIG. 3A), resulting in the positioning of a liquid layer 220′ on the intervening layer 310 (see FIG. 3A) and/or on the perovskite layer 210 (see FIG. 2). Referring to FIG. 2, for the example when a liquid layer 220 is applied directly to a surface of a perovskite layer 210, a liquid 122 photoresist may penetrate into the voids 215 present in the perovskite layer 210, resulting in intermediate device 115B. In some embodiments of the present disclosure, as shown in FIG. 2, a liquid 122 photoresist may completely fill the voids 215. However, in some embodiments of the present disclosure, a liquid 122 photoresist may only partially fill one or more voids 215. The degree to which a void 215 is filled with liquid 122 may depend on variety of factors, including but not limited to the viscosity and/or surface tension of the liquid 122, as well as the degree to which the perovskite layer 210 repels or attracts the liquid 122 photoresist.

Referring again to FIG. 3A, for the example that includes the depositing of an intervening layer 310, at least a portion of a liquid 122 photoresist may be transferred through the intervening layer 310 to the underlying perovskite layer 210, resulting in intermediate device 115B′. As a result of this transfer of material, at least a portion of any voids 215 remaining after the depositing 300 of an intervening layer 310 (see void labeled 215B) may be filled by liquid 122 photoresist. Further, although not shown in FIG. 3A, in some embodiments of the present disclosure, due to the transfer of liquid 122 photoresist through an intervening layer 310, an intervening layer 310 itself may contain a non-negligible amount of liquid 122 photoresist, within its boundaries as defined by the thickness of the intervening layer 310. For example, an intervening layer 310 constructed of one or more monolayers of graphene may include an empty volume, which may be at least partially filled by a liquid 122 photoresist during the applying 120 of a liquid layer 220′ of photoresist to the surface of the intervening layer 310.

In some embodiments of the present disclosure, the applying 120 of a liquid 122 photoresist onto an intermediate device (e.g., 115A or 115A′) may be achieved by at least one of dip-coating, curtain-coating, blade-coating, slot-die coating, gravure coating, bar-coating, inkjet printing, and/or spray-coating. In some embodiments of the present disclosure, the applying 120 may be performed at a temperature between about 10° C. and 100° C. and/or with the liquid layer of 220 photoresist maintained at a temperature between about 10° C. and 100° C. In some embodiments of the present disclosure, the applying 120 may be performed at a pressure less than or equal to about 2 atmospheres of pressure (absolute pressure). In some embodiments of the present disclosure, the applying 120 may be performed in vacuum, i.e., a pressure of less than 1 atmosphere. In some embodiments of the present disclosure, the applying 120 may be performed in an environment that includes at least one of oxygen, nitrogen, or a noble gas (e.g., helium, neon, argon, and/or xenon). In some embodiments of the present disclosure, the applying 120 may be completed in an air environment. In some embodiments of the present disclosure, a liquid layer 220 of photoresist may be allowed to “sit” on the intermediate device (115B or 115B′) for a period of time, to give the liquid 122 sufficient time to penetrate into voids within the perovskite layer 210. In some embodiments of the present disclosure, such a period of time may be between one second and one hour in duration.

In some embodiments of the present disclosure, a liquid 122 photoresist may include a monomer such as at least one of an alkene, an epoxide, a cinnamate or other ester and/or ether, an acrylate, phenol, a phenoloic, azides, Novolak, an isoprene, an oxetane, a coumarin, an anthracene, a maleimide, a furan, and/or styrene. Further, a liquid 122 photoresist may also include mixed with appropriate monomers, radical initiators, or other polymerization agents to achieve a suitable molecular weight. For example, Novolak is a family of phenol-based polymers produced by the condensation with formaldehyde and contains a diazonaphthoquinone for development under illumination to produce a pattern. In some embodiments of the present disclosure, a liquid 122 photoresist may be epoxy free. In some embodiments of the present disclosure, a liquid 122 photoresist may have a viscosity at the processing temperature between 1 cSt and 10,000 cSt or between 1,000 cSt and 5,000 cSt. In some embodiments of the present disclosure, a liquid 122 photoresist may have a density of greater than 0.8 g/cm³ or between 0.8 g/cm³ and 1.5 g/cm³. These liquid 122 photoresists, when cured by exposure to light 234, result in polymerized versions of the starting liquid 122 photoresists. For example, a liquid 122 photoresist, once cured/polymerized may include at least one of a polyether, a polyacrylate, a polyalkene (e.g., polyethylene, polypropylene), a phenolic resin, etc. Specific liquid 122 photoresists tested herein include the following industrially available trade names: SU-8, Mr-NIL210, and NMF HAR1.

Referring again to FIGS. 2-3A, the voids 215 illustrated in these figures have a relatively large depth in the y-direction relative to a relatively narrow width in the x-direction. In terms of an aspect ratio, width divided by depth, the aspect ratio shown is less than one. However, this is shown for illustrative purposes. FIG. 3B illustrates another possibility, according to some embodiments of the present disclosure, with an aspect ratio of greater than one. Here, the width of the voids 215 illustrated (in the x-direction) are significantly larger than the depth of the voids 215 (in the y-direction). So, the aspect ratio in terms of width to depth in the example illustrated in FIG. 3B is relatively large, e.g., greater than one. The representation shown in FIG. 3B may be more common than that shown in FIG. 3A. Experience has shown that when depositing perovskite layers having thicknesses on the order of hundreds of nanometers can often have voids, e.g., pin-holes on the order of micrometers is not uncommon and can result from environmental contamination (dust), de-wetting of the liquid perovskite precursor from the underlying substrate, and/or surface defects and non-uniformities in the substrates. Regardless of the aspect ratio of voids 215 (either like those shown in FIG. 3A or FIG. 3B), the methods described herein are effective at minimizing or eliminating the negative consequences of leaving such voids untreated.

Referring again to FIGS. 1-3A, and 3B, once a liquid 122 photoresist has been applied to an intermediate device (115A or 115A′), resulting in an intermediate device (115B or 115B′) having a liquid layer (220 or 220′) and liquid 122 photoresist penetrating into one or more voids 115 contained in the underlying perovskite layer 210, a method (100 or 100A) may proceed with the polymerizing/curing (i.e., solidification) of the liquid layer 220 photoresist by irradiating 130 the “front-side” of the intermediate device (115B or 115B′) with light 234. The irradiating 130 step results in the desired consequence of converting the liquid-filled defects (i.e., voids) into solid-filled defects, thereby eliminating, or at least reducing, the probability of electrical shunts forming during subsequent processing steps (e.g., the addition of an electrode layer, etc.).

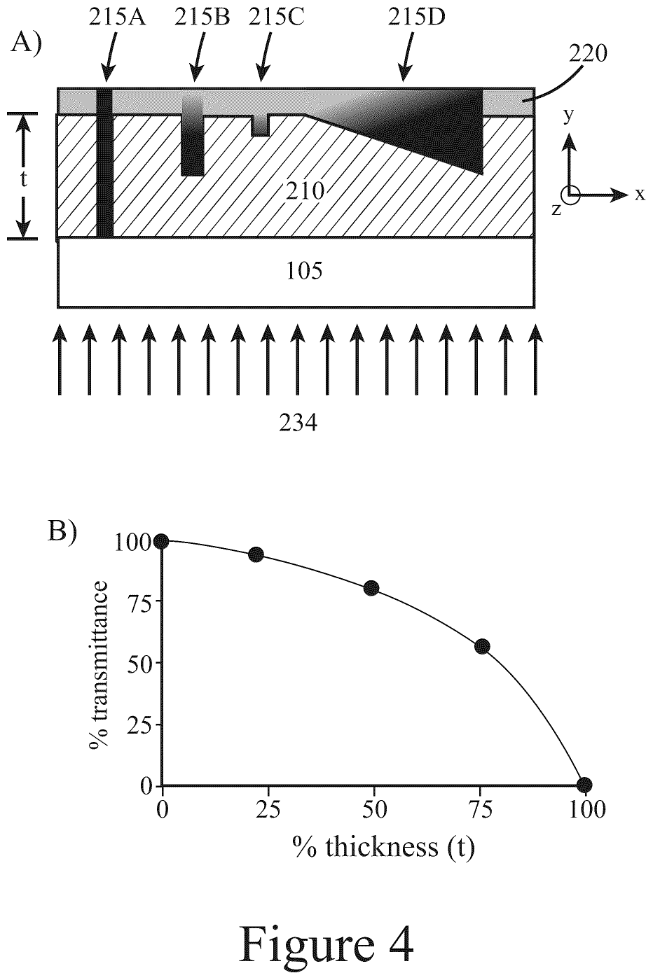

FIG. 4 illustrates an important relationship between the thickness (t) of a perovskite layer 210 and the amount of light 234 transmitted through the perovskite layer 210 and how these two factors can affect the degree of polymerization/curing of a liquid layer 220 of photoresist, depending on its location within the thickness of the perovskite layer 210. Panel A of FIG. 4 illustrates a simplified cross-section of perovskite layer 210 positioned on a transparent substrate 105. This intermediate device 115 has an average thickness (t), as measured in the y-axis direction and four exemplary voids (215A-215D) that penetrate into variable portions of the thickness of the perovskite layer 210. A liquid layer 220 of photoresist is positioned on the top surface of the perovskite layer 210, with the liquid indicated by the light to dark shading. Liquid 122 that has solidified due to its exposure to light 234 is shaded black, with partially cured photoresist having intermediate shading between the light gray for liquid and the black for solid. Void 215A penetrates through the entire thickness of the perovskite layer 210 and, as a result, receives 100% of the light transmitted through the substrate 105 resulting in the entire void 215A being converted to a solid, as indicated by the black fill. As the penetration of the voids lessens, for example as shown for voids 215B and 215C, a larger percentage of the light 234 is absorbed by the perovskite material and less light is transmitted to the liquid layer 220 of photoresist, resulting in lesser amounts of these voids being converted from liquid to solid.

This relationship between light transmitted versus thickness of a hypothetical perovskite layer 210 is shown in Panel B of FIG. 4. Here, % light transmittance versus perovskite layer thickness is shown as a non-linear equation, for illustrative purposes; the relationship may also be linear, depending on the perovskite composition, impurities that may be present, etc. For example, the relationship may be inverted with transmittance decaying exponentially with thickness. Regardless of the shape, less light is transmitted as the light passes from the substrate 105 through the thickness of the perovskite layer 210. Because of this relationship, void 215A, which receives 100% of the light transmitted through the substrate 105 is completely solidified, including the liquid column above the void 215A. Void 215B is not as deep as void 215B and for the same exposure time, receives less light and may result in a lesser degree of polymerization. Void 215C is even shallower than void 215B and, therefore, in this hypothetical case, only partially cures. Void 215D is illustrated as a large defect and illustrates how the amount of liquid 122 photoresist that cures in the y-axis direction is proportional to the depth that a void penetrates into the perovskite layer and the percentage of the light that is transmitted through the perovskite layer 210. In some embodiments of the present disclosure, a perovskite layer 210 may have an average thickness between 500 nm and 1000 nm, such that less than 5% or less than 1% of the light 234 utilized during the irradiating 130 is transmitted through the full thickness of the perovskite layer 210. Illumination time or illumination intensity in step 132 may be modulated to increase or decrease the degree of polymerization within both deep and shallow voids.

In some embodiments of the present disclosure, a light source 232 may be a halogen light, a laser (e.g., UV laser), a sulfur-plasma lamp, an arc lamp, a mercury arc lamp, and/or a light-emitting diode (LED). In some embodiments of the present disclosure, a light source 232 may emit a light 234 having a spectrum including wavelengths less than 400 nm. In some embodiments of the present disclosure, a light source 232 may emit a light 234 having a wavelength spectrum including a range between 200 nm and 400 nm. Regardless of the wavelength of light 234, the key design criterium is that the selected wavelength of light 234 cause the liquid layer 220 of photoresist to react and solidify. In some embodiments of the present disclosure, a typical light source may emit a power output between 1 mW/m² and 100 mW/m² or between 1 mW/m² and 10 mW/m², while a laser or intense pulsed light may have orders of magnitude higher power output. In some embodiments of the present disclosure, the total energy provided to a liquid layer 220 of a photoresist may be between 1 mJ and 1000 mJ or between 50 mJ and 600 mJ. In some embodiments of the present disclosure, a bank of two or more light sources 232 may be utilized to irradiate a liquid layer 220 of photoresist. In some embodiments of the present disclosure, a light source 232 may be flat panel positioned substantially parallel to the front side of the intermediate device (115 or 115′), rather than the spherical light source 232 illustrated in FIGS. 2 and 3. In some embodiments of the present disclosure, a light source 232 may be positioned at a distance between one millimeter and one meter from the outer surface of a substrate 105. In some embodiments of the present disclosure, irradiating 130 may be performed for a period of time of less than 60 seconds or less than 30 seconds.

Referring again to FIGS. 1-3, once an irradiating 130 step has been completed and the liquid 122 photoresist present in the voids 215 at least partially polymerized/cured (i.e., solidified), a method 100 may continue with the removing 140 of any remaining uncured and/or marginally cured liquid 122 photoresist from the intermediate device (115C or 115C′), resulting in the targeted improved device (155 or 155′). In some embodiments of the present disclosure. The removing 140 of uncured liquid 122 photoresist may be accomplished using a removal liquid 142, for example, a liquid that can at least one of physically displace the liquid 122 photoresist and/or solubilize the uncured liquid 122 photoresist. Importantly, a removal liquid 142 should not react with and/or cause the degradation of the solidified photoresist. Examples of removal liquids 142 include toluene and/or an alcohol (e.g., isopropyl alcohol and/or trifluoroethanol). A removing 140 step may be achieved in a variety of ways. These include passing the intermediated device 115C through a bath of the removal liquid 142, spraying the removal liquid 142 onto the intermediate device 115C/115C′ and letting the used removal liquid 146 drain off the surface of the intermediated device 115C/115C′ by gravity, and/or by passing the intermediate device 115C/115C′ through a curtain of the removal liquid 142 and, again, letting the used removal liquid 146 drain off the surface of the intermediated device 115C/115C′ by gravity. In some embodiments of the present disclosure, a removal liquid 142 may be applied using blade coating, followed by removing 140 of excess removal liquid 142 (e.g., by gravity), followed by drying with an air knife. In some embodiments of the present disclosure, this sequence of three steps, application of a removal liquid, removal of excess removal liquid, and drying with an air knife, may be repeated between once and 10 times or between once and three times. In some examples, a removal liquid may be applied using an immersion bath and/or sonication.

In some embodiments, one or more regions of solid 240 (cured photoresist) may be partially or fully removed with a subsequent removal step. In one embodiment, this is applied to solid 240 infilling P2 module scribe lines whereby the partial or full removal of solid 240 with additional scribing enables subsequent deposition of a conductive interconnection layer between module subcells.

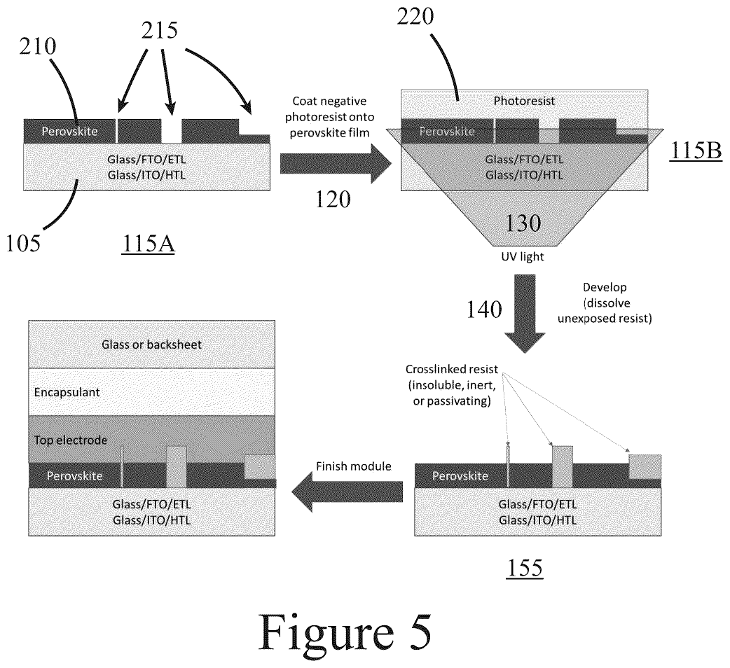

FIG. 5 illustrates an exemplary method for treating a device having a perovskite layer with various defects, according to some embodiments of the present disclosure. As described above, such a method can remove physical defects (voids, pinholes, scratches) present in halide perovskite layers 210 by utilizing and curing a liquid 122 photoresist to prevent the subsequent formation of shunts, thereby enabling the manufacture of high-performance perovskite photovoltaic modules irrespective of perovskite layer coverage. At large scale (e.g. on the order of 1 m²), non-uniformities (e.g. voids, pinholes, scratches, dust particles, spikes) in coating perovskite thin film layers are nearly unavoidable. Completion of such a device by deposition of the top electrode likely leads to shunts that reduce the efficiency of the solar module (or general optoelectronic device) and locally create Joule heating, which can compromise the longevity of the product. One alternative to the methods described herein is to make a photovoltaic absorber layer much thicker than necessary (e.g. 5 μm), but this does not fully solve the issues and can lead to performance losses due to other factors. Thus, in some embodiments of the present disclosure, the physical weak points in thin films including, but not limited to, non-optimally thin regions, pinholes, voids, etc. may be filled, partially filled, and/or capped with an electrically insulating polymer. This renders these minute regions electrically inactive, and allows the top electrode to be deposited, for example, without making direct contact to the bottom electrode via a pinhole.

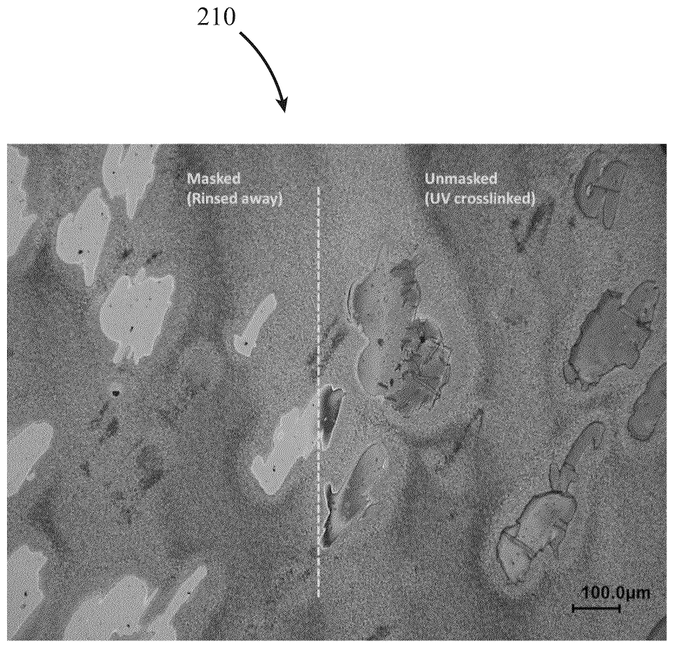

FIG. 6 illustrates an exemplary perovskite layer treated according to such a method, thereby proving the validity of the concept. In this example, electrical tape was applied to the device to mask, i.e., block the UV light, with the tape applied to the left of the dotted yellow line, so that no UV light reached that portion of the film. Although, the entire layer was coated with a photoresist, only the unmasked portion (exposed to UV light) remained, as a solid, after developing. Thus, referring again to FIG. 6, “masked” is equivalent to non-irradiated and unmasked on the right is irradiated. The entire left side of the layer (masked) had photoresist on it but did not receive a dose of illumination and, therefore, did not cure/solidify. However, the entire area of right side (unmasked) of the layer received illumination. However, for this portion of the layer, the perovskite layer itself acted as a mask to the illumination so that photoresist was only irradiated and cured in the voided areas. Typically, photoresists are cured with short wavelength light (e.g. 300-450 nm wavelengths). The only requirement for the perovskite (including compositional and thickness properties) is that it absorbs the majority of the light (>90%). For most perovskite materials, this may be achieved using a minimum thickness of ˜50 nm and no upper limit to the thickness.

FIG. 7 illustrates how the methods described herein may be used multiple times during the fabrication of a device, according to some embodiments of the present disclosure. For example, a method for treating voids may be first applied after the depositing of a perovskite layer, thereby treating any inadvertent defects resulting from the perovskite deposition step; e.g., defects caused by the coating process; e.g., blade coating, slot-die coating, gravure printing, screen printing, and/or a vapor deposition method. Subsequent module manufacturing steps include the forming of P2 scribes which intentionally deletes regions of perovskite active layer (including other layers) leaving areas of exposed bottom contact as well as exposed perovskite on the side walls of the scribes. Metallization or top electrode deposition occurs after P2 scribes. The method for treating voids may be applied a second time to file the P2 scribes to prevent direct perovskite-metal contact from occurring during the deposition of a metal and/or top electrode layer. After metallization, a P3 scribe is cut to isolate individual cells which can also be a source of defects or degradation in a module. Among other things, filling P2 and/or P3 scribes with photoresist will likely improve module stability by: 1) inhibiting metal diffusion into the perovskite, 2) inhibiting corrosion of the metal by egressing halide species, 3) inhibiting ingress of O₂ and H₂O into the perovskite, and 4) improving mechanical adhesion and mechanical robustness.

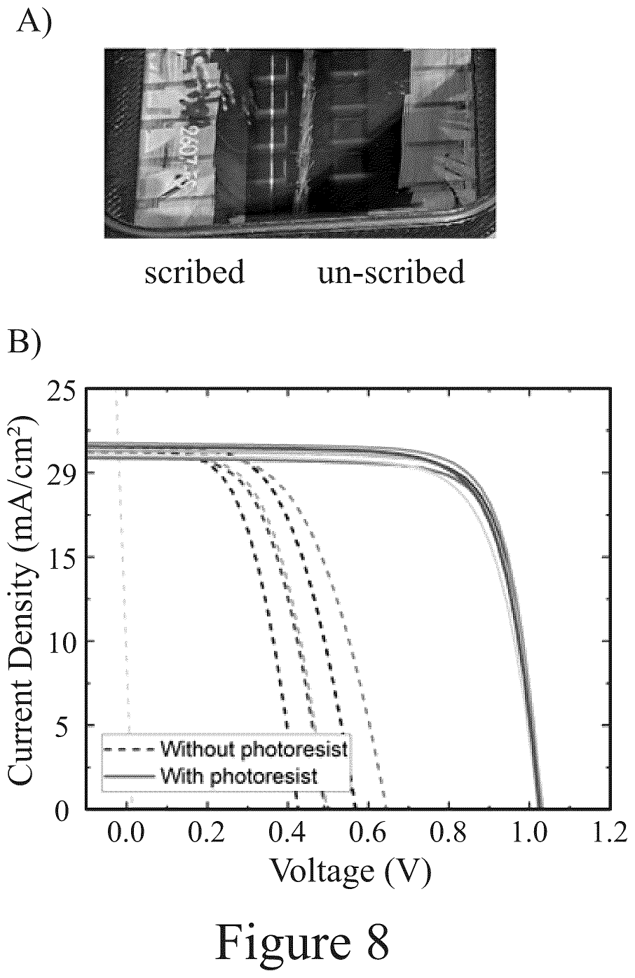

FIG. 8 illustrates (Panel A) a photograph of a device where the left side was treated using the methods described herein and the right side was untreated and (Panel B) a comparison of current-voltage curves obtained for both devices treated using the methods described herein versus untreated, according to some embodiments of the present disclosure. To confirm that the application of photoresist improves device performance when physical defects are present, a mechanical scribe was intentionally created through the perovskite layer on half of the active device areas on a single substrate (Panel A, left side). The remaining devices were left intact to serve as controls (Panel B, right side). Then, the sample was either coated with photoresist (mr-NIL210FC) and exposed to UV light to selectively crosslink the resist at the scribed region or left untreated after the scribe. The excess photoresist was removed by rinsing the device with anisole. The device was then completed with a thermally evaporated silver electrode (100 nm thick) and measured under a calibrated solar simulator. As shown in the IV characteristics (Panel B), the devices without photoresist suffer from severe loss in fill factor and open circuit voltage, while the devices treated with photoresist maintain the performance of their intact counterparts, with only a slight loss of current density due to the physically removed perovskite region. The device stack used for this demonstration was: glass/ITO/hole transport material/formamidinium-cesium containing perovskite/C₆₀ (25 nm)/ALD deposited SnOₓ (15 nm)/Ag (100 nm).

### EXAMPLES

Example 1. A method comprising, in order: applying a liquid to a first surface of a perovskite layer, the perovskite layer having an average thickness defined by a distance between the first surface and a second surface; and irradiating the second surface with a light; wherein: the perovskite layer includes a void that penetrates into the first surface and at least a portion of the thickness, the applying results in at least a portion of the liquid at least partially filling the void, and the irradiating results in the liquid in the void reacting to form a solid.

Example 2. The method of Example 1, wherein the void is completely filled by the solid.

Example 3. The method of either Example 1 or Example 2, wherein the irradiating lowers a solubility of a compound in the liquid, resulting in the solid.

Example 4. The method of any one of Examples 1-3, wherein the average thickness of the perovskite layer, without voids, results in essentially zero transmission of the light between the wavelengths of 200 nm and 400 nm from the second surface to the first surface.

Example 5. The method of any one of Examples 1-4, wherein the light spectrum includes at least one wavelength of less than or equal to 500 nm.

Example 6. The method of any one of Examples 1-5, wherein the light spectrum includes at least one wavelength between 200 nm and 500 nm or between 300 nm and 450 nm.

Example 7. The method of any one of Examples 1-1, wherein the irradiating is performed for a period of time of less than 60 seconds.

Example 8. The method of any one of Examples 1-7, wherein the period of time is less than 30 seconds.

Example 9. The method of any one of Examples 1-1, wherein the average thickness is between 400 nm and 1000 nm.

Example 10. The method of any one of Examples 1-1, wherein the void has an average diameter in the plane of the perovskite layer of less than or equal to one centimeter.

Example 11. The method of any one of Examples 1-10, wherein the average diameter is between 1 nm and 1 mm.

Example 12. The method of any one of Examples 1-1, further comprising, before the applying, depositing an intervening layer onto the first surface of the perovskite layer.

Example 13. The method of any one of Examples 1-12, wherein the intervening layer comprises at least one of an organic, an oxide, a carbonaceous material, or a combination thereof.

Example 14. The method of any one of Examples 1-13, wherein the oxide comprises at least one of tin oxide, nickel oxide, titanium oxide, zinc oxide, aluminum-doped zinc oxide, molybdenum oxide, vanadium oxide, indium tin oxide, zinc tin oxide, or a combination thereof

Example 15. The method of any one of Examples 1-13, wherein the carbonaceous material comprises at least one of a fullerene, graphene, a carbon nanotube, or a combination thereof.

Example 16. The method of any one of Examples 1-15, wherein the carbon nanotube comprises at least one of a single-walled carbon nanotube, a double-walled carbon nanotube, a multi-walled carbon nanotubes, or a combination thereof.

Example 17. The method of any one of Examples 1-13, wherein the organic comprises naphthalene diimide.

Example 18. The method of any one of Examples 1-12, further comprising, after the irradiating, removing unreacted liquid remaining on at least one of the first surface of the perovskite layer or on the intervening layer.

Example 19. The method of any one of Examples 1-18, wherein the removing is performed physically, by gravity, by use of a removal liquid, or a combination thereof.

Example 20. The method of any one of Examples 1-19, wherein the removing is performed by contacting the perovskite layer and unreacted liquid with the removal liquid.

Example 21. The method of any one of Examples 1-20, wherein the contacting comprises passing the perovskite layer and unreacted liquid through a curtain of the removal liquid.

Example 22. The method of any one of Examples 1-18, wherein the perovskite layer has a low solubility or zero solubility in the liquid, during the applying, irradiating, and removing.

Example 23. The method of any one of Examples 1-18, wherein at least one of the applying, irradiating, or removing is performed at a temperature between 10° C. and 100° C. or between 20° C. and 30° C.

Example 24. The method of any one of Examples 1-18, wherein at least one of the applying, irradiating, or removing is performed at a pressure between 0.1 atm and 5 atm absolute or between 0.9 atm and 1.1 atm absolute.

Example 25. The method of any one of Examples 1-18, wherein at least one of the applying, irradiating, or removing is performed with a gas head-space comprising at least one of air or an inert gas.

Example 26. The method of any one of Examples 1-18, wherein the liquid has minimal reactivity or zero reactivity with the perovskite layer, during the applying, irradiating, and removing.

Example 27. The method of any one of Examples 1-1, wherein the applying is performed using at least one of blade coating, slot die-coating, curtain-coating, gravure coating, ink jet printing, spray coating, bar-coating, or a combination thereof.

Example 28. The method of any one of Examples 1-1, wherein the void comprises a scribe.

Example 29. The method of any one of Examples 1-1, wherein the void comprises at least one of a hole, a pin-hole, a crack, a thinner portion of the perovskite layer, a scribe, a grain boundary, or a combination thereof.

Example 30. The method of any one of Examples 1-29, wherein the thinner portion has a thickness of less than 200 nm or less than 100 nm.

Example 31. The method of any one of Examples 1-30, wherein the void penetrates the entire thickness of the perovskite layer, or 90% of the thickness of the perovskite layer, or 60% of the thickness of the perovskite layer, or 40% of the thickness of the perovskite layer, or 20% of the thickness of the perovskite layer, or 10% of the thickness of the perovskite layer.

Example 32. The method of any one of Examples 1-31, wherein the liquid comprises a monomer comprising at least one of an alkene, an epoxide, an ester, an acrylate, phenol, a phenoloic, azides, an isoprene, an oxetane, a coumarin, an anthracene, a maleimide, a furan, styrene, or a combination thereof.

Example 33. The method of any one of Examples 1-32, wherein the liquid further comprises a polymerizing agent.

Example 34. The method of any one of Examples 1-33, wherein the polymerizing agent comprises a radical initiator.

Example 35. The method of any one of Examples 1-34, wherein the solid comprises a polymerized form of the monomer.

Example 36. The method of any one of Examples 1-35, wherein the polymerized form of the monomer comprises at least one of a polyether, a polyacrylate, a polyalkene, a phenolic resin, a polyester, polystyrene, or a combination thereof.

Example 37. The method of any one of Examples 1-36, wherein, during the applying, the liquid has a viscosity between 1 cSt and 10,000 cSt or between 1,000 cSt and 5,000 cSt.

Example 38. The method of any one of Examples 1-37, wherein, during the applying, the liquid has a density of greater than 0.8 g/cm³ or between 0.8 g/cm³ and 1.5 g/cm³.

Example 39. The method of any one of Examples 1-38, further comprising, after the removing, a second removing of excess liquid by drying the perovskite layer.

Example 40. The method of any one of Examples 1-39, wherein the drying is performed using an air knife.

Example 41. The method of any one of Examples 1-40, wherein at least of the removing and the second removing are completed between once and 10 times or between once and three times.

Example 42. A device comprising: a perovskite layer comprising a void, wherein: the void is at least partially filled with at least one of a polymer, a resin, or a combination thereof.

Example 43. The device of Example 42, wherein the void comprises at least one of a hole, a pin-hole, a crack, a thinner portion of the perovskite layer, a scribe, a grain boundary, or a combination thereof.

Example 44. The device of either Example 42 or Example 43, wherein the void comprises a scribe.

Example 45. The device of any one of Examples 42-44, wherein the perovskite layer has an average thickness between 400 nm and 1000 nm.

Example 46. The device of any one of Examples 42-45, wherein the perovskite comprises ABX₃, X is an anion, A is a first cation, and B is a second cation.

Example 47. The device of any one of Examples 42-46, further comprising an intervening layer positioned in physical contact with the perovskite.

Example 48. The device of any one of Examples 42-47, further comprising a charge transport layer wherein the intervening layer is positioned between the charge transport layer and the perovskite layer.

Example 49. The device of any one of Examples 42-48, further comprising an electrode layer, wherein the charge transport layer is positioned between the electrode layer and the intervening layer.

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The foregoing discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

What is claimed is:

1. A method comprising, in order:
applying a liquid to a first surface of a perovskite layer, the perovskite layer having an average thickness defined by a distance between the first surface and a second surface; and
irradiating the second surface with a light; wherein:
the perovskite layer includes a void that penetrates into the first surface and at least a portion of the thickness,
the applying results in at least a portion of the liquid at least partially filling the void, and
the irradiating results in the liquid in the void reacting to form a solid.

2. The method of claim 1, wherein the void is completely filled by the solid.

3. The method of claim 1, wherein the average thickness of the perovskite layer, without voids, results in essentially zero transmission of the light between the wavelengths of 200 nm and 400 nm from the second surface to the first surface.

4. The method of claim 3, wherein the light includes comprises a wavelength of less than or equal to 500 nm.

5. The method of claim 1, wherein the average thickness is between 400 nm and 1000 nm.

6. The method of claim 1, further comprising, before the applying, depositing an intervening layer onto the first surface of the perovskite layer.

7. The method of claim 6, wherein the intervening layer comprises at least one of an organic, an oxide, a carbonaceous material, or a combination thereof.

8. The method of claim 1, further comprising, after the irradiating, removing unreacted liquid remaining on at least one of the first surface of the perovskite layer or on the intervening layer.

9. The method of claim 8, wherein the removing is performed physically, by gravity, by use of a removal liquid, or a combination thereof.

10. The method of claim 8, wherein at least one of the applying, irradiating, or removing is performed at a temperature between 10° C. and 100° C.

11. The method of claim 1, wherein the void comprises at least one of a hole, a pin-hole, a crack, a thinner portion of the perovskite layer, a scribe, a grain boundary, or a combination thereof.

12. The method of claim 1, wherein the liquid comprises a monomer.

13. The method of claim 12, wherein the monomer comprising at least one of an alkene, an epoxide, an ester, an acrylate, phenol, a phenoloic, azides, an isoprene, an oxetane, a coumarin, an anthracene, a maleimide, a furan, styrene, or a combination thereof.

14. The method of claim 12, wherein the liquid further comprises a polymerizing agent.

15. The method of claim 14, wherein the polymerizing agent comprises a radical initiator.

16. The method of claim 12, wherein the solid comprises a cured form of the monomer.

17. The method of claim 16, wherein the cured form of the monomer comprises at least one of a polyether, a polyacrylate, a polyalkene, a phenolic resin, a polyester, polystyrene, or a combination thereof.

18. The method of claim 1, wherein, during the applying, the liquid has a viscosity between 1 cSt and 10,000 cSt or between 1,000 cSt and 5,000 cSt.

19. A device comprising:
a perovskite layer comprising a void, wherein:
the void is at least partially filled with at least one of a polymer, a resin, or a combination thereof.
